(19) United States
(12) Patent Application Publication
(10) Pub. No.: US 2006/0226853 A1
(43) Pub. Date: Oct. 12, 2006

(54) Test converting card and test apparatus thereof

(75) Inventors: Chih-Hung Wang, Taipei (TW); Chun-Fong Cheng, Taipei (TW); Hsiang-Ming Lee, Taipei (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: ASUSTeK Computer, Inc.

(21) Appl. No.: 11/388,690

(22) Filed: Mar. 24, 2006

(30) Foreign Application Priority Data
Apr. 11, 2005 (TW) 94111344

(51) Int. Cl. G01R 31/02

(52) U.S. Cl. 324/537

(57) ABSTRACT

A test converting card for testing an integrated circuit connector is described. The test converting card includes a test circuit board, an integrated circuit connector adapter, and a plurality of connectors. The integrated circuit connector adapter is disposed on one side of the test circuit board and the connectors are disposed on the other side thereof. The integrated circuit connector adapter is utilized to connect to an integrated circuit connector of a circuit board under test. The connectors electrically couple to the integrated circuit connector adapter by the interior circuit of the test circuit board. In combination with a manufacturing defects analyzer or an in-circuit testing equipment, a defect cause of a semi-finished product or an electronic appliance having an integrated circuit connector with quantities of pins can be quickly discovered.

### RELATED APPLICATIONS

The present application is based on, and claims priority from, Taiwan Application Serial Number 94111344, filed Apr. 11, 2005, the disclosure of which is hereby incorporated by reference herein in its entirety.

### FIELD OF THE INVENTION

The present invention generally relates to a test converting card for testing an integrated circuit connector. More particularly, this invention relates to a test converting card for testing an integrated circuit connector of a printed circuit board.

### BACKGROUND OF THE INVENTION

Because semiconductor manufacturing processes have progressed along with increasingly demanding functional requirements of semiconductor devices, electronic circuit layouts of the semiconductor devices have become increasingly more complicated and sophisticated. For example, an electronic circuit layout of a new generation central processing unit (CPU) is more complicated because the new generation CPU has to provide more powerful functions for users and software applications.

For working together with other electronic components mounted on circuit board, the quantity of input/output pins of powerful semiconductor chips have gradually increased. In general, a semiconductor chip has more than one hundred pins for transmitting data and power; and a central processing unit has significantly more. Conventionally, when fixing the semiconductor chip onto a printed circuit board, a connector is first fixed onto the printed circuit board and then the semiconductor chip is coupled to the connector. By way of the connector soldered on the printed circuit board, the damage rate of the expensive semiconductor chip can be effectively reduced and the semiconductor chip can be conveniently changed.

Even so, during manufacturing or utilization stages, parts of semi-finished products or electronic appliances with semiconductor chips may become damaged. Traditionally, a repairer has to find a defect cause first and then repair it. However, in this moment, various other electronic components or protecting components, such as Mylar films or insulation tapes, have already been fixed on the printed circuit board. Accordingly, a testing apparatus, such as a manufacturing defects analyzer (MDA) or an in-circuit testing equipment (ICT), with dedicated probes and used on the production line is not suitable to test the printed circuit board of the semi-finished product or the electronic appliance.

When the defect on the electronic appliance or the semi-finished product is not caused by the semiconductor chip itself, may be caused by the printed circuit board or other electronic component on the printed circuit board, a repairer normally uses a multimeter, for example, a volt-ohm-milliamp meter, to examine the connector of the semiconductor chip for judging the defect cause. As the number of pins of the semiconductor chip increase with strides in technology, the repairer must work harder and harder to repair a defect. For example, for a connector of a 478-pin Pentium 4 CPU a seasoned repairer needs about 30 to 40 minutes to find the defect pin; and an average repairer has to spend considerably more time.

Accordingly, if the repairer can quickly find the defect cause and repair it immediately, the repair efficiency can be improved, the manufacturing cost can be reduced, and the yield rate of the production line can also be improved when the production engineer improves the process parameters and/or the working standards according to the root causes of the defects.

### SUMMARY OF THE INVENTION

It is an objective of the present invention to provide a test converting card to quickly find root courses of defects for repairers so as to efficiently repair a defective product.

It is another objective of the present invention to provide a test converting card in conjunction with a manufacturing defects analyzer (MDA) or an in-circuit testing equipment (ICT) to expedite tests on a defective printed circuit board and electronic components thereon.

To accomplish the above objectives, the present invention provides a test converting card suitable for testing a semi-finished product, for example, a computer motherboard. The test converting card includes a connector adapter and a plurality of testing connectors. The connector adapter is disposed on one side of a printed circuit board for coupling to an integrated circuit connector of a circuit board under test. The testing connectors are disposed on another side of the printed circuit board to connect the connector adapter with interior circuits of the printed circuit board. The testing connectors are utilized to electrically couple to a testing equipment, for example, a manufacturing defects analyzer (MDA) or an in-circuit testing equipment (ICT), to detect a defect site on the circuit board under test by way of the connector adapter and the integrated circuit connector.

The test converting card is preferably utilized to test a central processing unit connector. For example, the test converting card is utilized to test a Pentium 4 connector having 478 pins. The testing connector preferably adopts 8 insulation displacement connectors (IDCs), each having 64 pins, to connect with the testing equipment and thereby quickly perform tests on the circuit board of the semi-finished product. The testing equipment can further utilize a computer to analyze and compare the data so as to find the root cause of the defect and improve the manufacturing process.

The test converting card can effectively avoid interferences with the electronic components and protection components on a circuit board of an electronic appliance or a semi-finished product, and in conjunction with the ICT or MDA testing equipment, can accelerate determining the defect causes of the semi-finished products or the electronic appliances. Accordingly, the repairer can efficiently find the defect causes and defect sites on the circuit board so as to improve the repair efficiency and the production line yield rate.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 illustrates a preferred embodiment of a test converting card according to the present invention; and

FIG. 2 illustrates a preferred embodiment of a test apparatus including the test converting card according to the present invention.

### DETAILED DESCRIPTION OF THE PREFERRED EMBODIMENT

The following description is of the best presently contemplated mode of carrying out the present invention. This description is not to be taken in a limiting sense but is made merely for the purpose of describing the general principles of the invention. The scope of the invention should be determined by referencing the appended claims.

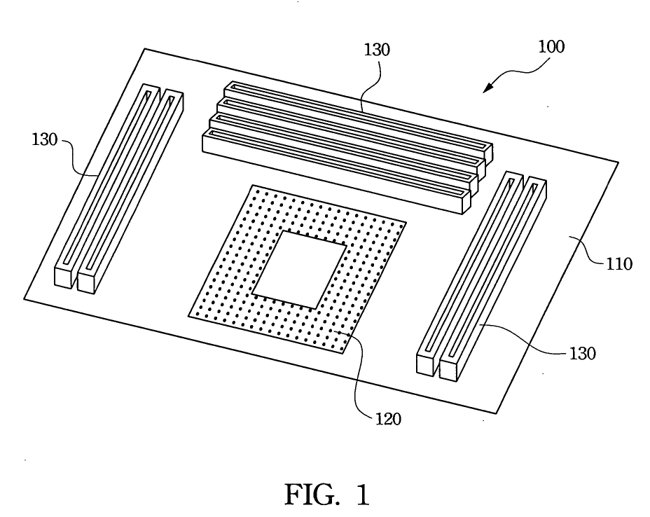

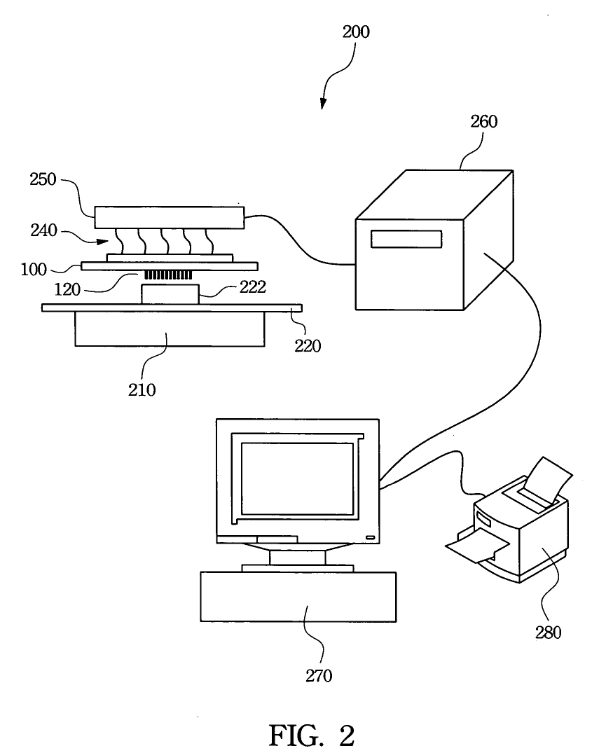

FIG. 1 illustrates a preferred embodiment of a test converting card according to the present invention. A test converting card 100 includes a test circuit board 110, an integrated circuit connector adapter 120, and a plurality of connectors 130. The integrated circuit connector adapter 120 is utilized to electrically couple to an integrated circuit connector on a circuit board under test (referring to FIG. 2). The integrated circuit connector adapter 120 includes a plurality of pins with similar or equal quantity to that of the integrated circuit connector on the circuit board under test for inserting into the integrated circuit connector.

On the test circuit board 110, the pins of the integrated circuit connector adapter 120 are electrically coupled to corresponding pins of the connectors 130 respectively. The connectors 130, such as insulation displacement connectors, are utilized to couple to a testing equipment, such as a manufacturing defects analyzer (MDA) or an in-circuit testing equipment (ICT). Accordingly, the testing equipment can effectively test the integrated circuit connector and the printed circuit board under test by way of the test converting card 100.

While comparing data measured by the test converting card 100 of a normal circuit board with the defective circuit board, the testing equipment can immediately find the abnormal pin of the integrated circuit connector on the defective circuit board to determine the defect cause of the circuit board and repair the same.

Because the connectors 130 can be common connectors of popular testing equipment, the test converting card 100 can conveniently adapt to the popular testing equipment. The connector 130 can correspond to the connector of a testing equipment; alternatively, the connector of the testing equipment can correspond to the connector 130 of the test converting card 100. Since the integrated circuit connector adapter 120 allows the testing equipment to directly connect to the pins of the integrated circuit connector under test and avoids touching the other electronic components and protection components, through the test converting card 100, the testing equipment can quickly test the defective circuit board.

However, in a traditional repairing process, a seasoned repairer utilizes simple testing equipment to test the pins of the integrated circuit connector on a defective circuit board. With the test converting card according to the present invention, the testing equipment needs only about 5 to 10 seconds to test a connector having about 500 pins and the circuits connected to the connector, and immediately reports the defect cause to the repairer. The defect causes of the semi-finished products can therefore immediately be found and the engineers of the production line can be informed to modify and improve manufacturing processes so as to effectively reduce the defect rate of the production line.

FIG. 2 illustrates a preferred embodiment of a test apparatus including the test converting card according to the present invention. The test apparatus 200 includes an upper supporting board 250, a stage 210, a test converting card 100, a testing equipment 260, and flat cables 240. When a circuit board 220 is under test, the circuit board 220 is first placed on the stage 210 and an integrated circuit connector 222 of the circuit board 220 is aligned to the integrated circuit connector adapter 120 of the test converting card 100 to allow pins of the integrated circuit connector adapter 120 to insert into the integrated circuit connector 222.

Meanwhile, another side of the test converting card 100 couples to the upper supporting board 250 and electrically connects to the testing equipment 260 via the flat cables 240. The testing equipment preferably adopts the testing equipment with the multi-site detecting function, for example, the MDA or the ICT. By way of the test converting card 100, the detected signals from the integrated circuit connector 222 of the circuit board 220 are transmitted to the testing equipment 260 for determining defect causes of the circuit board 220.

The testing equipment 260 further includes a computer 270 and a printer 280 to analyze and output the defect causes and data so that the production engineer may improve the process according to the defect reasons and data.

The test converting card according to the present invention can avoid interferences with the electronic components and protection components on a circuit board under test of an electronic appliance or a semi-finished product thereby allowing ICT or MDA to directly analyze the IC connector and the circuit board. Accordingly, the test converting card can accelerate the judgments of the defect causes and defect sites so as to enhance the repairing efficiency and production yield. The test converting card according to the present invention preferably performs tests on a Pentium 4 connector having 478 pins or a circuit board with a connector having greater than 478 pins. The test converting card adopts the insulation displacement connector with 64 pins to connect to the testing equipment so as to correctly test on a motherboard and immediately report the defect causes of the motherboard. Accordingly, the defect cause for manufacturing the motherboard can be found and improved quickly. Hence, the test converting card according to the present invention and the test apparatus with the testing converting card can quickly sense production defects and therefore improve the defective process and defective components thereof so as to efficiently improve the yield rate of the production line.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

What is claimed is:

1. A test converting card, comprising:
a testing equipment;
a connector adapter with a plurality of pins for coupling to a connector under test of a circuit board under test; and
a plurality of testing connectors with a plurality of pins and the pins of the testing connectors respectively coupling to the pins of the connector adapter, wherein the testing connectors are electrically connecting to the testing equipment to detect a defect site on the circuit board under test by way of the connector adapter and the connector under test.

2. The test converting card of claim 1, wherein the testing equipment comprises a manufacturing defects analyzer (MDA).

3. The test converting card of claim 1, wherein the testing equipment comprises an in-circuit testing equipment (ICT).

4. The test converting card of claim 1, wherein the testing connector comprises an insulation displacement connector.

5. The test converting card of claim 1, wherein the connector under test is an integrated circuit connector.

6. The test converting card of claim 5, wherein the integrated circuit connector is an integrated circuit connector for coupling to a Pentium 4 central processing unit.

7. The test converting card of claim 6, wherein the Pentium 4 central processing unit has 478 pins.

8. The test converting card of claim 7, wherein the testing connector is composed of a plurality of insulation displacement connectors.

9. The test converting card of claim 7, wherein the testing connector is composed of 8 insulation displacement connectors disposed around the test converting card.

10. The test converting card of claim 9, wherein each of the insulation displacement connectors has 64 pins.

11. A test apparatus, comprising:
a testing equipment;
a plurality of flat cables connecting to the testing equipment; and
a testing converting card, further comprising:
a connector adapter with a plurality of pins for coupling to a connector under test of a circuit board under test; and
a plurality of testing connectors with a plurality of pins and the pins of the testing connectors respectively electrically connecting to the pins of the connector adapter, wherein the testing connectors are electrically connecting to the flat cables to detect a defect site on the circuit board under test by way of the connector adapter and the connector under test.

12. The test apparatus of claim 11, wherein the testing equipment comprises a manufacturing defects analyzer (MDA).

13. The test apparatus of claim 11, wherein the testing equipment comprises an in-circuit testing equipment (ICT).

14. The test apparatus of claim 11, wherein the testing connectors comprise insulation displacement connector connectors.

15. The test apparatus of claim 14, wherein each of the flat cables further comprises a corresponding insulation displacement connector to connect to the insulation displacement connector.

16. The test apparatus of claim 11, wherein the connector adapter is utilized to couple to a central processing unit connector.

17. The test apparatus of claim 16, wherein the central processing unit connector is utilized to couple to a Pentium 4 central processing unit.

18. The test apparatus of claim 17, wherein the Pentium 4 central processing unit has 478 pins.

19. The test converting card of claim 18, wherein the testing connector is composed of 8 insulation displacement connectors.

20. The test apparatus of claim 19, wherein each of the insulation displacement connectors includes 64 pins.
